(19) United States
(12) Patent Application Publication
(10) Pub. No.: US 2013/0052333 A1
(43) Pub. Date: Feb. 28, 2013

(54) DEPOSITION SYSTEMS HAVING REACTION CHAMBERS CONFIGURED FOR IN-SITU METROLOGY AND RELATED METHODS

(71) Applicants: Ed Lindow, Scottsdale, AZ (US); Ronald Bertram, Mesa, AZ (US); Claudio Canizares, Chandler, AZ (US)

(72) Inventors: Ed Lindow, Scottsdale, AZ (US); Ronald Bertram, Mesa, AZ (US); Claudio Canizares, Chandler, AZ (US)

(73) Assignee: SOITEC, Crolles Cedex (FR)

(21) Appl. No.: 13/327,302

(22) Filed: Dec. 15, 2011

Related U.S. Application Data
(60) Provisional application No. 61/526,137, filed on Aug. 22, 2011.
(60) Provisional application No. 61/526,143, filed on Aug. 22, 2011.
(60) Provisional application No. 61/526,148, filed on Aug. 22, 2011.

(51) Int. Cl. C23C 16/52; B23Q 3/00

(52) U.S. Cl. 427/8; 118/712; 29/464

(57) ABSTRACT

Deposition systems include a reaction chamber, at least one thermal radiation emitter for heating matter within the reaction chamber, and at least one metrology device for detecting and/or measuring a characteristic of a workpiece substrate in situ within the reaction chamber. One or more chamber walls may be transparent to the thermal radiation and to radiation signals to be received by the metrology device, so as to allow the radiation to pass into and out from the reaction chamber, respectively. At least one volume of opaque material is located to shield a sensor of the metrology device from at least some of the thermal radiation. Methods of forming a deposition system include providing such a volume of opaque material at a location shielding the sensor from the thermal radiation. Methods of using a deposition system include shielding the sensor from at least some of the thermal radiation.

### CROSS-REFERENCE TO RELATED APPLICATIONS

The subject matter of this application is related to the subject matter of provisional U.S. patent application Ser. No. 61/526,137, which was filed Aug. 22, 2011 in the name of Bertram et al. and entitled “DEPOSITION SYSTEMS HAVING ACCESS GATES AT DESIRABLE LOCATIONS, AND RELATED METHODS,” to the subject matter of provisional U.S. patent application Ser. No. 61/526,143, which was filed Aug. 22, 2011 in the name of Bertram et al. and entitled “DEPOSITION SYSTEMS INCLUDING A PRECURSOR GAS FURNACE WITHIN A REACTION CHAMBER, AND RELATED METHODS,” and to the subject matter of provisional U.S. patent application Ser. No. 61/526,148, which was filed Aug. 22, 2011 in the name of Bertram and entitled “DIRECT LIQUID INJECTION FOR HALIDE VAPOR PHASE EPITAXY SYSTEMS AND METHODS,” the entire disclosure of each of which application is hereby incorporated herein in its entirety by this reference.

### FIELD

Embodiments of the invention generally relate to systems for depositing materials on substrates, and to methods of making and using such systems. More particularly, embodiments of the invention relate to vapor phase epitaxy (VPE) and chemical vapor deposition (CVD) methods for depositing III-V semiconductor materials on substrates and to methods of making and using such systems.

### BACKGROUND

Chemical vapor deposition (CVD) is a chemical process that is used to deposit solid materials on substrates, and is commonly employed in the manufacture of semiconductor devices. In chemical vapor deposition processes, a substrate is exposed to one or more reagent gases, which react, decompose, or both react and decompose in a manner that results in the deposition of a solid material on the surface of the substrate.

One particular type of CVD process is referred to in the art as vapor phase epitaxy (VPE). In VPE processes, a substrate is exposed to one or more reagent vapors in a reaction chamber, which react, decompose, or both react and decompose in a manner that results in the epitaxial deposition of a solid material on the surface of the substrate. VPE processes are often used to deposit III-V semiconductor materials. When one of the reagent vapors in a VPE process comprises a hydride vapor, the process may be referred to as a hydride vapor phase epitaxy (HVPE) process.

HVPE processes are used to form III-V semiconductor materials such as, for example, gallium nitride (GaN). In such processes, epitaxial growth of GaN on a substrate results from a vapor phase reaction between gallium chloride (GaCl) and ammonia (NH₃) that is carried out within a reaction chamber at elevated temperatures between about 500° C. and about 1,100° C. The NH₃ may be supplied from a standard source of NH₃ gas.

In some methods, the GaCl vapor is provided by passing hydrogen chloride (HCl) gas (which may be supplied from a standard source of HCl gas) over heated liquid gallium (Ga) to form GaCl in situ within the reaction chamber. The liquid gallium may be heated to a temperature of between about 750° C. and about 850° C. The GaCl and the NH₃ may be directed to (e.g., over) a surface of a heated substrate, such as a wafer of semiconductor material. U.S. Pat. No. 6,179,913, which issued Jan. 30, 2001 to Solomon et al., discloses a gas injection system for use in such systems and methods, the entire disclosure of which patent is hereby incorporated herein by reference.

In such systems, it may be necessary to open the reaction chamber to atmosphere to replenish the source of liquid gallium. Furthermore, it may not be possible to clean the reaction chamber in situ in such systems.

To address such issues, methods and systems have been developed that utilize an external source of a GaCl₃ precursor, which is directly injected into the reaction chamber. Examples of such methods and systems are disclosed in, for example, U.S. Patent Application Publication No. US 2009/0223442 A1, which published Sep. 10, 2009 in the name of Arena et al., the entire disclosure of which publication is incorporated herein by reference.

### BRIEF SUMMARY

This summary is provided to introduce a selection of concepts in a simplified form, such concepts being further described in the detailed description below of some example embodiments of the invention. This summary is not intended to identify key features or essential features of the claimed subject matter, nor is it intended to be used to limit the scope of the claimed subject matter.

In some embodiments, the present disclosure includes deposition systems. The deposition systems include a reaction chamber having one or more chamber walls. At least one thermal radiation emitter is configured to emit thermal radiation through at least one chamber wall of the one or more chamber walls and into an interior of the reaction chamber. The thermal radiation may include wavelengths within a range of wavelengths in at least one of the infrared region and the visible region of the electromagnetic radiation spectrum. The at least one chamber wall through which the thermal radiation is transmitted comprises a transparent material that is at least substantially transparent to electromagnetic radiation over the range of wavelengths. The deposition systems further include at least one metrology device including a sensor. The sensor is located outside the reaction chamber and oriented and configured to receive an electromagnetic radiation signal passing from an interior of the reaction chamber to an exterior of the reaction chamber. The electromagnetic radiation signal may comprise one or more wavelengths within the range of wavelengths over which the thermal radiation is emitted. At least one volume of opaque material is located to prevent at least some thermal radiation to be emitted by the at least one thermal radiation emitter from being detected by the sensor of the at least one metrology device. The opaque material is opaque to wavelengths of electromagnetic radiation within the range of wavelengths over which the thermal radiation is emitted.

In additional embodiments, the present disclosure includes methods of forming deposition systems. At least one thermal radiation emitter may be positioned outside and proximate to a reaction chamber including one or more chamber walls. The at least one thermal radiation emitter may be oriented to emit thermal radiation through at least one chamber wall of the one or more chamber walls and into an interior of the reaction chamber. The at least one thermal radiation emitter may comprise an emitter configured to emit thermal radiation within a range of wavelengths of electromagnetic radiation in at least one of the infrared region and the visible region of the electromagnetic radiation spectrum. The at least one chamber wall through which the thermal radiation is emitted may be selected to comprise a transparent material that is at least substantially transparent to electromagnetic radiation over the range of wavelengths over which the thermal radiation is emitted. A sensor of at least one metrology device may be positioned outside and proximate to the reaction chamber. The sensor may be oriented to receive an electromagnetic radiation signal passing from an interior of the reaction chamber to an exterior of the reaction chamber. The sensor may be selected to comprise a sensor that is configured to detect the electromagnetic radiation signal at one or more wavelengths within the range of wavelengths over which the thermal radiation is emitted by the one or more thermal radiation emitters. At least one volume of opaque material is provided at a location preventing at least some thermal radiation emitted by the at least one thermal radiation emitter from being detected by the sensor of the at least one metrology device. The opaque material may be selected to comprise a material opaque to wavelengths of electromagnetic radiation within the range of wavelengths over which the thermal radiation is emitted.

In yet further embodiments, the present disclosure includes methods of depositing material on workpiece substrates using deposition systems. At least one workpiece substrate may be positioned within an interior of a reaction chamber. Thermal radiation may be emitted into the interior of the reaction chamber from at least one thermal radiation emitter located outside the reaction chamber through at least a portion of one or more chamber walls of the reaction chamber. The one or more chamber walls through which the thermal radiation is emitted may comprise a transparent material that is transparent to the thermal radiation. At least one process gas may be introduced into the reaction chamber. At least one of the workpiece substrate and the at least one process gas may be heated by the thermal radiation. Material may be deposited on the at least one workpiece substrate from the at least one process gas. A sensor of at least one metrology device may be used to sense an electromagnetic radiation signal representative of at least one characteristic of the workpiece substrate. The sensor may be located outside and proximate to the reaction chamber. The electromagnetic radiation signal sensed by the sensor may pass from the interior of the reaction chamber to the sensor through one or more chamber walls of the reaction chamber transparent to the electromagnetic radiation signal. The sensor may be shielded from at least some of the thermal radiation emitted by the thermal radiation emitter using at least one volume of opaque material.

### BRIEF DESCRIPTION OF THE DRAWINGS

The present disclosure may be understood more fully by reference to the following detailed description of example embodiments, which are illustrated in the appended figures in which:

FIG. 1 is a cut-away perspective view schematically illustrating an example embodiment of a deposition system including a volume of opaque material used to shield a sensor of a metrology device from thermal radiation emitted by a thermal radiation emitter of the deposition system;

FIG. 2 is a partial perspective view of the deposition system shown in FIG. 1;

FIGS. 3A through 3B are simplified and schematically illustrated graphs used to illustrate relationships between the wavelengths of the thermal radiation emitted by the thermal radiation emitters of the deposition system of FIGS. 1 and 2, and the transmissivity of transparent material (FIG. 3B) and opaque material (FIG. 3C), as a function of wavelength, of various components of the deposition system of FIGS. 1 and 2.

### DETAILED DESCRIPTION OF EMBODIMENTS OF THE INVENTION

The illustrations presented herein are not meant to be actual views of any particular system, component, or device, but are merely idealized representations that are employed to describe embodiments of the present invention.

As used herein, the term “III-V semiconductor material” means and includes any semiconductor material that is at least predominantly comprised of one or more elements from group IIIA of the periodic table (B, Al, Ga, In, and Ti) and one or more elements from group VA of the periodic table (N, P, As, Sb, and Bi). For example, III-V semiconductor materials include, but are not limited to, GaN, GaP, GaAs, InN, InP, InAs, AlN, AlP, AlAs, InGaN, InGaP, InGaNP, etc.

As used herein, the term “gas” includes gases (fluids that have neither independent shape nor volume) and vapors (gases that include diffused liquid or solid matter suspended therein), and the terms “gas” and “vapor” are used synonymously herein.

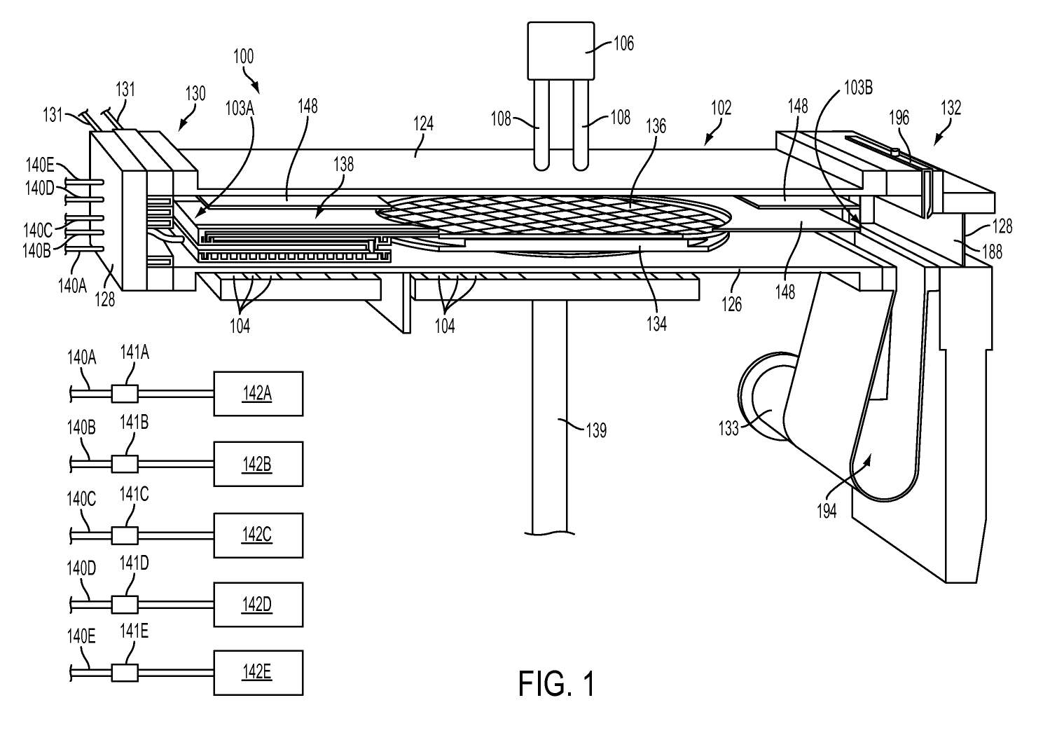

FIG. 1 illustrates an example of a deposition system 100 in accordance with the present disclosure. The deposition system 100 includes an at least substantially enclosed reaction chamber 102, at least one thermal radiation emitter 104, a metrology device 106, and a volume of opaque material (not illustrated in FIG. 1) configured and located to shield a sensor 108 of the metrology device 106 from at least some radiation emitted by the thermal radiation emitter 104. These components of the deposition system 100 are discussed in further detail below. In some embodiments, the deposition system 100 may comprise a CVD system, and may comprise a VPE deposition system (e.g., an HVPE deposition system).

The reaction chamber 102 may include one or more chamber walls. For example, the chamber walls may include a horizontally oriented top wall 124, a horizontally oriented bottom wall 126, and one or more vertically oriented lateral side walls 128 extending between the top wall 124 and the bottom wall 126.

The deposition system 100 may further include a gas injection device 130 used for injecting one or more process gases into the reaction chamber 102, and a venting and loading subassembly 132 used for venting process gases out from the reaction chamber 102 and for loading substrates into the reaction chamber 102 and unloading substrates out from the reaction chamber 102. The gas injection device 130 may be configured to inject one or more process gases through one or more of the lateral side walls 128 of the reaction chamber 102.

In some embodiments, the reaction chamber 102 may have the geometric shape of an elongated rectangular prism, as shown in FIG. 1. In some such embodiments, the gas injection device 132 may be located at a first end of the reaction chamber 102, and the venting and loading subassembly may be located at an opposing, second end of the reaction chamber 102. In other embodiments, the reaction chamber 102 may have another geometric shape.

The deposition system 100 includes a substrate support structure 134 (e.g., a susceptor) configured to support one or more workpiece substrates 136 on which it is desired to deposit or otherwise provide semiconductor material within the deposition system 100. For example, the one or more workpiece substrates 136 may comprise dies or wafers. As shown in FIG. 1, the substrate support structure 134 may be coupled to a spindle 139, which may be coupled (e.g., directly structurally coupled, magnetically coupled, etc.) to a drive device (not shown), such as an electrical motor that is configured to drive rotation of the spindle 139 and, hence, the substrate support structure 134 within the reaction chamber 102.

The deposition system 100 further includes a gas flow system used to flow process gases through the reaction chamber 102. For example, the deposition system 100 may comprise at least one gas injection device 130 for injecting one or more process gases into the reaction chamber 102 at a first location 103A, and a vacuum device 133 for drawing the one or more process gases through the reaction chamber 102 from the first location 103A to a second location 103B and for evacuating the one or more process gases out from the reaction chamber 102 at the second location 103B. The gas injection device 130 may comprise, for example, a gas injection manifold including connectors configured to couple with conduits carrying one or more process gases from process gas sources.

With continued reference to FIG. 1, the deposition system 100 may include five gas inflow conduits 140A-140E that carry gases from respective process gas sources 142A-142E to the gas injection device 130. Optionally, gas valves (141A-141E) may be used to selectively control the flow of gas through the gas inflow conduits 140A-140E, respectively.

In some embodiments, at least one of the gas sources 142A-142E may comprise an external source of at least one of GaCl₃, InCl₃, or AlCl₃, as described in U.S. Patent Application Publication No. US 2009/0223442 A1. GaCl₃, InCl₃ and AlCl₃ may exist in the form of a dimer such as, for example, Ga₂Cl₆, In₂Cl₆ and Al₂Cl₆, respectively. Thus, at least one of the gas sources 142A-142F may comprise a dimer such as Ga₂Cl₆, In₂Cl₆ or Al₂Cl₆.

In embodiments in which one or more of the gas sources 142A-142E is, or includes, a GaCl₃ source, the GaCl₃ source may include a reservoir of liquid GaCl₃ maintained at a temperature of at least 100° C. (e.g., approximately 130° C.), and may include physical means for enhancing the evaporation rate of the liquid GaCl₃. Such physical means may include, for example, a device configured to agitate the liquid GaCl₃, a device configured to spray the liquid GaCl₃, a device configured to flow carrier gas rapidly over the liquid GaCl₃, a device configured to bubble carrier gas through the liquid GaCl₃, a device, such as a piezoelectric device, configured to ultrasonically disperse the liquid GaCl₃, and the like. As a non-limiting example, a carrier gas, such as He, N₂, H₂, or Ar, may be bubbled through the liquid GaCl₃, while the liquid GaCl₃ is maintained at a temperature of at least 100° C., such that the source gas may include one or more carrier gases in which precursor gas is conveyed.

In some embodiments, the temperatures of the gas inflow conduits 140A-140E may be controlled between the gas sources 142A-142E and the reaction chamber 102. The temperatures of the gas inflow conduits 140A-140E and associated mass flow sensors, controllers, and the like, may increase gradually from a first temperature (e.g., about 100° C. or more) at the exit from the respective gas sources 142A-142E up to a second temperature (e.g., about 150° C. or less) at the point of entry into the reaction chamber 102 in order to prevent condensation of the gases (e.g., GaCl₃ vapor) in the gas inflow conduits 140A-140E. Optionally, the length of the gas inflow conduits 140A-140E between the respective gas sources 142A-142E and the reaction chamber 102 may be about three feet or less, about two feet or less, or even about one foot or less. The pressure of the source gases may be controlled using one or more pressure control systems.

In additional embodiments, the deposition system 100 may include less than five (e.g., one to four) gas inflow conduits and respective gas sources, or the deposition system 100 may include more than five (e.g., six, seven, etc.) gas inflow conduits and respective gas sources.

The one or more of the gas inflow conduits 140A-140E extend to the gas injection device 130. The gas injection device 130 may comprise one or more blocks of material through which the process gases are carried into the reaction chamber 102. One or more cooling conduits 131 may extend through the blocks of material. A cooling fluid may be caused to flow through the one or more cooling conduits 131 so as to maintain the gas or gases flowing through the gas injection device 130 by way of the gas inflow conduits 140A-140E within a desirable temperature range during operation of the deposition system 100. For example, it may be desirable to maintain the gas or gases flowing through the gas injection device 130 by way of the gas inflow conduits 140A-140E at a temperature less than about 200° C. (e.g., about 150° C.) during operation of the deposition system 100.

Optionally, the deposition system 100 may include an interior precursor gas furnace 138, as described in provisional U.S. patent application Ser. No. 61/526,143, which was filed Aug. 22, 2011 in the name of Bertram et al. and entitled “DEPOSITION SYSTEMS INCLUDING A PRECURSOR GAS FURNACE WITHIN A REACTION CHAMBER, AND RELATED METHODS,” the disclosure of which is hereby incorporated herein in its entirety by this reference.

With continued reference to FIG. 1, the venting and loading subassembly 132 may comprise a vacuum chamber 194 into which gases flowing through the reaction chamber 102 are drawn by a vacuum within the vacuum chamber 194 and vented out from the reaction chamber 102. The vacuum within the vacuum chamber 194 is generated by the vacuum device 133. As shown in FIG. 1, the vacuum chamber 194 may be located below the reaction chamber 102.

The venting and loading subassembly 132 may further comprise a purge gas curtain device 196 that is configured and oriented to provide a generally planar curtain of flowing purge gas, which flows out from the purge gas curtain device 196 and into the vacuum chamber 194. The venting and loading subassembly 132 also may include an access gate 188, which may be selectively opened for loading and/or unloading workpiece substrates 136 from the substrate support structure 134, and selectively closed for processing of the workpiece substrates 136 using the deposition system 100. In some embodiments, the access gate 188 may comprise at least one plate configured to move between a closed first position and an open second position. The access gate 188 may extend through a side wall of the reaction chamber 102 in some embodiments.

The reaction chamber 102 may be at least substantially enclosed, and access to the substrate support structure 134 through the access gate 188 may be precluded, when the plate of the access gate 188 is in the closed first position. Access to the substrate support structure 134 may be enabled through the access gate 188 when the plate of the access gate 188 is in the open, second position.

The purge gas curtain emitted by the purge gas curtain device 196 may reduce or prevent the flow of gases out from the reaction chamber 102 during loading and/or unloading of workpiece substrates 136.

Gaseous byproducts, carrier gases, and any excess precursor gases may be exhausted out from the reaction chamber 102 through the venting and loading subassembly 132.

The deposition system 100 may comprise a plurality of thermal radiation emitters 104, as illustrated in FIG. 1. The thermal radiation emitters 104 are configured to emit thermal radiation within a range of wavelengths of electromagnetic radiation in at least one of the infrared region and the visible region of the electromagnetic radiation spectrum. For example, the thermal radiation emitters 104 may comprise thermal lamps (not shown) configured to emit thermal energy in the form of electromagnetic radiation.

In some embodiments, the thermal radiation emitters 104 may be located outside and below the reaction chamber 102 adjacent the bottom wall 126. In additional embodiments, the thermal radiation emitters 104 may be located above the reaction chamber 102 adjacent the top wall 124, beside the reaction chamber 102 adjacent one or more lateral side walls 128, or at a combination of such locations.

The thermal radiation emitters 104 may be disposed in a plurality of rows of thermal radiation emitters 104, which may be controlled independently from one another. In other words, the thermal energy emitted by each row of thermal radiation emitters 104 may be independently controllable. The rows may be oriented transverse to the direction of the net flow of gas through the reaction chamber 102, which is the direction extending from left to right from the perspective of FIG. 1. Thus, the independently controlled rows of thermal radiation emitters 104 may be used to provide a selected thermal gradient across the interior of the reaction chamber 102, if so desired.

The thermal radiation emitters 104 may be located outside the reaction chamber 102 and configured to emit thermal radiation through at least one chamber wall of the reaction chamber 102 and into an interior of the reaction chamber 102. Thus, at least a portion of the chamber walls through which the thermal radiation is to pass into the reaction chamber 102 may comprise a transparent material, so as to allow efficient transmission of the thermal radiation into the interior of the reaction chamber 102. The transparent material may be transparent in the sense that the material may be at least substantially transparent to electromagnetic radiation at wavelengths corresponding to the thermal radiation emitted by the thermal radiation emitters 104. For example, at least about 80%, at least about 90%, or even at least about 95% of at least a range of the wavelengths of the thermal radiation emitted by the thermal radiation emitters 104 impinging on the transparent material may pass through the transparent material and into the interior of the reaction chamber 102.

As a non-limiting example, the transparent material may comprise a transparent refractory ceramic material, such as transparent quartz (i.e., silicon dioxide (SiO₂)). The transparent quartz may be fused quartz, and may have an amorphous microstructure. Any other refractory material that is both physically and chemically stable at the temperatures and in the environments to which the material is subjected during deposition processes using the deposition system 100, and that is sufficiently transparent to the thermal radiation emitted by the thermal radiation emitters 104, may be used to form one or more of the chamber walls of the deposition system 100 in further embodiments of the disclosure.

As shown in FIG. 1, in some embodiments, the thermal radiation emitters 104 may be disposed outside and below the reaction chamber 102 adjacent the bottom wall 126 of the reaction chamber 102. In such embodiments, the bottom wall 126 may comprise a transparent material, such as transparent quartz, so as to allow transmission of the thermal radiation emitted by the thermal radiation emitters 104 into the interior of the reaction chamber 102 as described above. Of course, thermal radiation emitters 104 may be provided adjacent other chamber walls of the reaction chamber 102 and at least a portion of such chamber walls also may comprise a transparent material as described herein.

As previously mentioned, the deposition system 100 may comprise one or more metrology devices 106 for detecting and/or measuring one or more characteristics of a workpiece substrate 136, or a material deposited on the workpiece substrate 136, in situ within the interior of the reaction chamber 102. The one or more metrology devices 106 may include, for example, one or more of a reflectometer, a deflectometer, and a pyrometer. Reflectometers are often used in the art to measure, for example, a growth rate and/or a topography of material being deposited on the workpiece substrate 136 in the reaction chamber 102. Deflectometers are often used in the art to measure planarity or non-planarity (e.g., bow) of the workpiece substrate 136 (and/or a material being deposited thereon). Pyrometers are often used in the art to measure a temperature of the workpiece substrate 136 within the reaction chamber 102. Such metrology devices 106 include one or more sensors 108 for detecting and/or measuring electromagnetic radiation at one or more predetermined wavelengths to effect their respective measurements. In some such metrology devices 106, the electromagnetic radiation to be received and detected may also be emitted by the metrology device 106. In other words, the metrology device 106 may emit electromagnetic radiation toward the workpiece substrate 136, and then detect the emitted electromagnetic radiation after it has been reflected, deflected, or otherwise affected by the workpiece substrate 136.

The one or more metrology devices 106 and associated sensors 108 may be located outside the reaction chamber 102. The sensors 108 may be oriented and configured to receive an electromagnetic radiation signal passing from an interior of the reaction chamber 102 to an exterior of the reaction chamber 102. For example, as shown in FIG. 1, the one or more metrology devices 106 and associated sensors 108 may be located over the reaction chamber 102 adjacent the top wall 124. In such configurations, the sensors 108 may be oriented and configured to receive an electromagnetic radiation signal passing through the top wall 124 from the interior of the reaction chamber 102 to the exterior of the reaction chamber 102. Thus, at least the portion of the chamber wall (e.g., the top wall 124) through which the electromagnetic radiation signal passes to reach the sensors 108 may be at least substantially transparent to the wavelength or wavelengths of electromagnetic radiation corresponding to the electromagnetic radiation signal to be received by the sensors 108. At least the portion of the chamber wall through which the electromagnetic radiation signal passes to reach the sensors 108 may comprise a transparent material as previously described herein, such as transparent quartz.

The wavelength or wavelengths of electromagnetic radiation corresponding to the electromagnetic radiation signal to be received by the sensors 108 may be within at least one of the infrared region and the visible region of the electromagnetic radiation spectrum, and may be within the range of wavelengths of electromagnetic radiation corresponding to the thermal radiation emitted by the thermal radiation emitters 104. As a result, stray electromagnetic radiation emitted by the thermal radiation emitters 104 may be received and detected by the sensors 108 of the one or more metrology devices 106, which may result in noise in the detected electromagnetic radiation signal, which can adversely affect the ability to obtain accurate measurements using the one or more metrology devices 106. Further, in some situations, the chamber walls of the reaction chamber 102 may serve to reflect and guide the thermal radiation emitted by the thermal radiation emitters 104 toward the sensors 108 of the one or more metrology devices 106.

Thus, in accordance with embodiments of the present disclosure, the deposition system 100 may further include one or more volumes of opaque material selectively located to prevent at least some of the thermal radiation emitted by the thermal radiation emitters 104 from being detected by the sensor 108 of the one or more metrology devices 106. The opaque material may be opaque to wavelengths of electromagnetic radiation within a range of wavelengths corresponding to the wavelengths of the thermal radiation emitted by the thermal radiation emitters 104. In other words, the opaque material may be opaque to at least a portion of the thermal radiation emitted by the thermal radiation emitters 104. For example, about 25% or less, about 15% or less, or even about 5% or less of at least a range of the wavelengths of the thermal radiation emitted by the thermal radiation emitters 104 impinging on a one millimeter thick sample of the opaque material may pass through the sample of opaque material.

As a non-limiting example, the opaque material may comprise an opaque refractory ceramic material, such as opaque quartz (i.e., silicon dioxide (SiO₂)). The opaque quartz may be fused quartz, and may have an amorphous microstructure. In some embodiments, the quartz may include microvoids (i.e., bubbles) or other inclusions that render the quartz opaque. Any other refractory material that is both physically and chemically stable at the temperatures and in the environments to which the material is subjected during deposition processes using the deposition system 100, and that is sufficiently opaque to the thermal radiation emitted by the thermal radiation emitters 104, may be used as the opaque material in accordance with embodiments of the disclosure.

As shown in FIG. 1, in some embodiments, one or more opaque bodies 148 each comprising a volume of such an opaque material may be positioned within the interior of the reaction chamber 102. The one or more opaque bodies 148 may comprise generally planar plate-shaped structures in some embodiments. In such embodiments, the generally planar plate-shaped structures may be horizontally oriented such that they extend generally parallel to the top wall 124 and the bottom wall 126, as shown in FIG. 1. The one or more opaque bodies 148 may be disposed between the top wall 124 and the bottom wall 126, and may be located and oriented to shield the sensor or sensors 108 from at least some of the thermal radiation emitted by the thermal radiation emitters 104. For example, a generally planar plate-shaped opaque body 148 may be located over the interior precursor gas furnace 148 proximate to the gas injection device 130, and additional generally planar plate-shaped opaque bodies 138 may be located proximate to the venting and loading subassembly 132, as shown in FIG. 1.

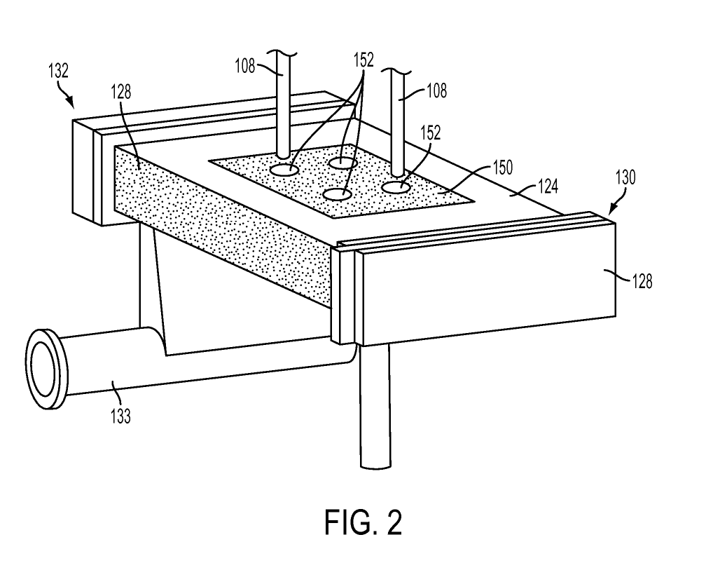

Further, at least a portion of one or more of the chamber walls may comprise a volume of opaque material. For example, FIG. 2 is a simplified perspective view of the deposition system 100 shown in FIG. 1. Opaque material is shaded with stippling in FIG. 2 to facilitate illustration of opaque regions of chamber walls.

As shown in FIG. 2, and with continued reference to FIG. 1, at least a portion of one or more of the lateral side walls 128 may comprise an opaque material. Such lateral side walls 128 may include the lateral side walls 128 that extend longitudinally along the reaction chamber 102 between the gas injection device 130 and the venting and loading subassembly 132. In the embodiment illustrated in FIG. 2, the lateral side walls 128 that extend longitudinally along the reaction chamber 102 are entirely formed of opaque material. In additional embodiments, only a portion of the lateral side walls 128 may comprise opaque material.

As previously mentioned, the sensors 108 of the one or more metrology devices 106 may be disposed outside the reaction chamber 102 adjacent a chamber wall of the reaction chamber 102. The chamber wall adjacent the sensors 108 may comprise one or more transparent portions, which may define windows through which an electromagnetic radiation signal may pass before impinging on a sensor 108, as well as one or more opaque portions shielding the sensor 108 from stray electromagnetic radiation emitted by the thermal radiation emitters 104. For example, in the embodiment of FIG. 2, the sensors 108 of the one or more metrology devices 106 (FIG. 1) are disposed adjacent the top wall 124. The top wall 124 includes a volume 150 of opaque material, and transparent windows 152 extending through the volume 150 of opaque material. Thus, an electromagnetic radiation signal may pass through the transparent windows 152 and impinge on the sensors 108, and the volume 150 of opaque material may shield the sensors 108 from electromagnetic radiation emitted by the thermal radiation emitters 104 (FIG. 1).

The volumes of opaque material of the chamber walls may be integral portions of the chamber walls, or they may comprise, for example, plates or other bodies of opaque material that are simply disposed adjacent, and optionally bonded to, the respective chamber walls. As a non-limiting example, the volume 150 of opaque material of the top wall 124 may comprise a generally planar plate-shaped structure formed of opaque material having apertures extending therethrough defining the windows 152. The plate-shaped opaque structure may be disposed on, and optionally bonded to, another generally planar plate-shaped transparent structure formed of transparent material, which forms a remaining portion of the top wall 124.

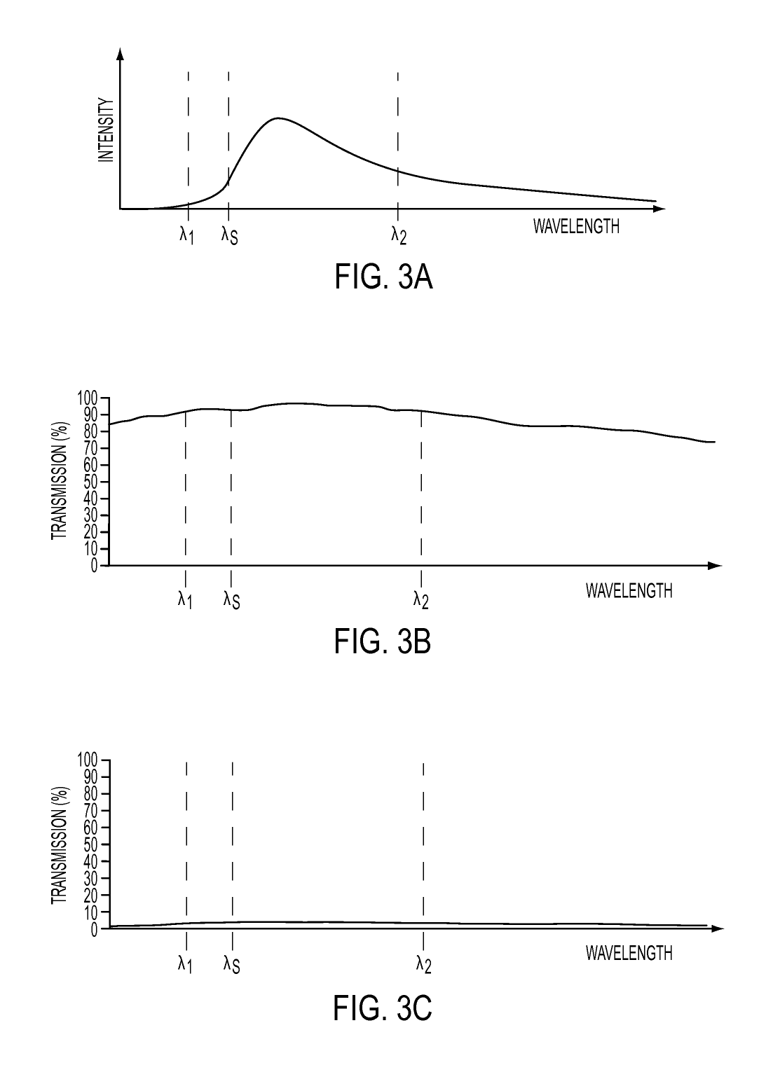

FIGS. 3A through 3C are graphs used to further describe embodiments of the present disclosure. FIG. 3A is a simplified and schematically illustrated graph showing an example of an emission spectrum for the thermal radiation that may be emitted by the thermal radiation emitters 104 (FIG. 1). In other words, FIG. 3A is a graph of the intensity of the emitted thermal radiation as a function of wavelength of the emitted thermal radiation. The wavelengths represented in FIG. 3A (as well as FIGS. 3B and 3C) extend from the visible region (e.g., from about 380 nm to about 760 nm) and into the infrared region (e.g., from about 750 nm to about 1.0 mm) of the electromagnetic radiation spectrum. FIG. 3B is a graph of the percentage of electromagnetic radiation that is transmitted through a one millimeter thick sample of the transparent material of one or more of the chamber walls, as previously described herein, as a function of wavelength over the same range of wavelengths represented in FIG. 3A. Similarly, FIG. 3C is a graph of the percentage of electromagnetic radiation that is transmitted through a one millimeter thick sample of an opaque material, as previously described herein, as a function of wavelength over the same range of wavelengths represented in FIGS. 3A and 3B.

Referring to FIG. 3A, in accordance with embodiments of the present disclosure, a range of wavelengths may be defined, such as a range extending from a first wavelength λ₁ to a second wavelength λ₂, within which the thermal radiation emitters 104 (FIG. 1) may be configured to emit thermal radiation. The thermal radiation emitters 104 may also emit thermal radiation at wavelengths outside the range of wavelengths between the first wavelength λ₁ and the second wavelength λ₂, but the thermal radiation is emitted over wavelengths that include the wavelengths between the first wavelength λ₁ and the second wavelength λ₂. The sensor 108 of the one or more metrology devices 106 (FIG. 1) may be oriented and configured to receive an electromagnetic radiation signal at one or more predetermined signal wavelengths, such as the signal wavelength λ_{S} shown in FIG. 3A, that is within the range of wavelengths extending between the first wavelength λ₁ and the second wavelength λ₂.

As previously mentioned, the thermal radiation emitters 104 (FIG. 1) may be configured to emit the thermal radiation through at least one chamber wall and into an interior region of the reaction chamber 102. The at least one chamber wall through which the thermal radiation is transmitted may comprise a transparent material that is at least substantially transparent to electromagnetic radiation to at least the wavelengths of radiation in the range extending from the first wavelength λ₁ to the second wavelength λ₂. For example, FIG. 3B illustrates how a graph of the percentage of electromagnetic radiation that is transmitted through a one millimeter thick sample of the transparent material of the one or more chamber walls through which the thermal radiation is transmitted, as a function of wavelength. As shown in FIG. 3B, the average transmittance of the transparent material may be at least about 80% over the range of the wavelengths extending from the first wavelength λ₁ to the second wavelength λ₂. In additional embodiments, an average transmittance of the transparent material may be at least about 90%, or even at least about 95%, over the range of the wavelengths extending from the first wavelength λ₁ to the second wavelength λ₂.

Additionally, as previously mentioned, the at least one volume of opaque material of the deposition system 100 that is used to shield the sensor or sensors 108 of the one or more metrology devices 106 from at least a portion of the thermal radiation emitted by the thermal radiation emitters 104 (FIG. 1) may be opaque to wavelengths of electromagnetic radiation within the range of wavelengths extending from the first wavelength λ₁ to the second wavelength λ₂. For example, FIG. 3C illustrates how a graph of the percentage of electromagnetic radiation that is transmitted through a one millimeter thick sample of the opaque material of the one or more chamber walls through which the thermal radiation is transmitted, as a function of wavelength. As shown in FIG. 3C, the average transmittance of the opaque material may be about 25% or less over the range of the wavelengths extending from the first wavelength λ₁ to the second wavelength λ₂. In additional embodiments, the average transmittance of the opaque material may be about 15% or less, or even about 5% or less, over the range of the wavelengths extending from the first wavelength λ₁ to the second wavelength λ₂.

In some embodiments, the above-described conditions may be met when the first wavelength λ₁ and the second wavelength λ₂ are defined such that the area under the emission spectrum curve for the thermal radiation emitted by the thermal radiation emitters 104 (such as that shown in FIG. 3A) encompasses at least about 50%, at least about 60%, or even at least about 70% of the total area under the section of the emission spectrum curve within the visible and infrared regions of the electromagnetic radiation spectrum (i.e., from 380 nm to 1.0 mm).

Additional embodiments of the present disclosure include methods of making and using deposition systems as described herein.

For example, referring again to FIGS. 1 and 2, a deposition system 100 may be formed by positioning one or more thermal radiation emitters 104 outside and proximate to a reaction chamber 102 including one or more chamber walls. The thermal radiation emitters 104 may be oriented to emit thermal radiation through at least one chamber wall and into an interior of the reaction chamber 102. The thermal radiation emitters 104 may be selected to comprise an emitter configured to emit thermal radiation within a range of wavelengths of electromagnetic radiation in at least one of the infrared region and the visible region of the electromagnetic radiation spectrum. The range of wavelengths may extend from a first wavelength λ₁ to a second wavelength λ₂, as described above with reference to FIGS. 3A through 3C.

At least one of the chamber walls may be selected to comprise a transparent material that is at least substantially transparent to electromagnetic radiation over the range of wavelengths, as described above with reference to FIG. 3B.

A sensor 108 of at least one metrology device 106 may be positioned outside and proximate to the reaction chamber 102, and the sensor 108 may be oriented to receive an electromagnetic radiation signal passing from an interior of the reaction chamber 102 to an exterior of the reaction chamber 102. Further, the sensor 108 may be selected such that the sensor 108 is configured to detect the electromagnetic radiation signal at one or more wavelengths within the range of wavelengths, such as the signal wavelength λ_{S} described herein with reference to FIGS. 3A through 3C.

At least one volume of opaque material may be provided at a location preventing at least some thermal radiation to be emitted by the one or more thermal radiation emitters 104 from being detected by the sensor 108 of the one or more metrology devices 106. The opaque material may be selected to comprise a material opaque to wavelengths of electromagnetic radiation within the range of wavelengths extending from the first wavelength λ₁ to the second wavelength λ₂, as previously described with reference to FIG. 3C. In some embodiments, one or more of the chamber walls may be selected to comprise the at least one volume of opaque material. In addition or as an alternative, an opaque body may be selected that comprises the opaque material, and the opaque body may be positioned within the interior of the reaction chamber 102. The body may be selected to comprise a generally planar plate-shaped structure.

Optionally, the reaction chamber 102 may comprise a top wall 124, a bottom wall 126, and at least one lateral side wall 128 extending between the top wall 124 and the bottom wall 126. In such embodiments, the one or more thermal radiation emitters 104, optionally, may be positioned outside and below the reaction chamber 102 adjacent the bottom wall 126 in some embodiments, and the sensor 108 of the one or more metrology devices 106 may be positioned outside and above the reaction chamber 102 adjacent the top wall 124. In such embodiments, the bottom wall 126 may be selected to comprise the transparent material. Further, at least one of the top wall 124 and the at least one lateral side wall 128 may be selected to comprise the at least one volume of opaque material. In addition or as an alternative, an opaque body 148 may be selected and positioned within the interior of the reaction chamber 102 as previously discussed with reference to FIG. 1.

As non-limiting examples, the transparent material may comprise a transparent quartz material, and the opaque material may comprise an opaque quartz material, as previously discussed.

Methods of using deposition systems 100 may be performed in accordance with further embodiments of the present disclosure. At least one workpiece substrate 136 may be positioned within an interior of a reaction chamber 102. Thermal radiation may be emitted into the interior of the reaction chamber 102 from at least one thermal radiation emitter 104 outside the reaction chamber 102 through one or more chamber walls of the reaction chamber 102 comprising a transparent material that is transparent to the thermal radiation. At least one precursor gas may be introduced into the reaction chamber 102, and at least one of the workpiece substrate 136 and the at least one precursor gas may be heated using the thermal radiation. Material may be deposited on the workpiece substrate 136 within the reaction chamber 102 from the at least one precursor gas. A sensor 108 of at least one metrology device 106 may be used to sense an electromagnetic radiation signal that represents at least one characteristic of the workpiece substrate 136 (such as, for example, a characteristic of the material being deposited on the workpiece substrate 136). The sensor 108 may be positioned outside and proximate to the reaction chamber 102. The electromagnetic radiation signal that is sensed by the sensor 108 may pass from the interior of the reaction chamber 102 to the sensor 108 through at least a portion of one or more chamber walls of the reaction chamber 102 that is transparent to the electromagnetic radiation signal. The sensor 108 may be shielded from at least some of the thermal radiation emitted by the at least one thermal radiation emitter 104 using at least one volume of opaque material, as previously described herein. For example, the sensor 108 may be shielded from at least some of the thermal radiation using at least one chamber wall of the reaction chamber 102 comprising at least one volume of opaque material. In addition or as an alternative, the sensor 108 may be shielded from at least some of the thermal radiation using at least one opaque body 148 positioned in the interior of the reaction chamber 102, as previously described.

Additional non-limiting example embodiments of the disclosure are set forth below.

### Embodiment 1

A deposition system, comprising: a reaction chamber including one or more chamber walls; at least one thermal radiation emitter configured to emit thermal radiation within a range of wavelengths of electromagnetic radiation in at least one of the infrared region and the visible region of the electromagnetic radiation spectrum through at least one chamber wall of the one or more chamber walls and into an interior of the reaction chamber, the at least one chamber wall comprising a transparent material at least substantially transparent to electromagnetic radiation over the range of wavelengths; at least one metrology device including a sensor located outside the reaction chamber and oriented and configured to receive an electromagnetic radiation signal at one or more wavelengths within the range of wavelengths passing from an interior of the reaction chamber to an exterior of the reaction chamber; and at least one volume of opaque material, the opaque material being opaque to wavelengths of electromagnetic radiation within the range of wavelengths, the at least one volume of the opaque material located to prevent at least some thermal radiation to be emitted by the at least one thermal radiation emitter from being detected by the sensor of the at least one metrology device.

### Embodiment 2

The deposition system of Embodiment 1, wherein the at least one volume of opaque material comprises at least a portion of a chamber wall of the one or more chamber walls.

### Embodiment 3

The deposition system of Embodiment 1, further comprising a body positioned within the interior of the reaction chamber, the body comprising the at least one volume of opaque material.

### Embodiment 4

The deposition system of Embodiment 3, wherein the body positioned within the interior of the reaction chamber comprises a generally planar plate-shaped structure.

### Embodiment 5

The deposition system of any one of Embodiments 1 through 3, wherein the one or more chamber walls of the reaction chamber include a top wall, a bottom wall, and at least one side wall extending between the top wall and the bottom wall.

### Embodiment 6

The deposition system of Embodiment 5, wherein the at least one thermal radiation emitter is disposed adjacent the bottom wall.

### Embodiment 7

The deposition system of Embodiment 5 or Embodiment 6, wherein the bottom wall comprises the transparent material.

### Embodiment 8

The deposition system of Embodiment 7, wherein the bottom wall comprises transparent quartz.

### Embodiment 9

The deposition system of any one of Embodiments 5 through 8, wherein at least a portion of the top wall comprises a volume of opaque material, such as opaque quartz.

### Embodiment 10

The deposition system of any one of Embodiments 5 through 9, wherein at least a portion of the at least one side wall comprises a volume of opaque material, such as opaque quartz.

### Embodiment 11

The deposition system of any one of Embodiments 5 through 10, wherein the sensor of the at least one metrology device is disposed adjacent the top wall.

### Embodiment 12

The deposition system of any one of Embodiments 5 through 11, wherein the at least one thermal radiation emitter is disposed outside the reaction chamber adjacent the bottom wall, at least a portion of the bottom wall comprises the transparent material, and the sensor of the at least one metrology device is disposed outside the reaction chamber adjacent the top wall.

### Embodiment 13

The deposition system of Embodiment 12, wherein at least one of the top wall and the at least one side wall comprises the at least one volume of opaque material.

### Embodiment 14

The deposition system of Embodiment 13, further comprising another volume of opaque material disposed within the interior of the reaction chamber between the top wall and the bottom wall.

### Embodiment 15

The deposition system of Embodiment 12, wherein the at least one volume of opaque material is disposed within the interior of the reaction chamber between the top wall and the bottom wall.

### Embodiment 16

The deposition system of any one of Embodiments 1 through 15, wherein the at least one thermal radiation emitter comprises a plurality of lamps.

### Embodiment 17

The deposition system of Embodiment 1, wherein the transparent material comprises transparent quartz.

### Embodiment 18

The deposition system of any one of Embodiments 1 through 17, wherein the opaque material comprises opaque quartz.

### Embodiment 19

A method of forming a deposition system, comprising: positioning at least one thermal radiation emitter outside and proximate to a reaction chamber including one or more chamber walls; orienting the at least one thermal radiation emitter to emit thermal radiation through at least one chamber wall of the one or more chamber walls and into an interior of the reaction chamber; selecting the at least one thermal radiation emitter to comprise an emitter configured to emit thermal radiation within a range of wavelengths of electromagnetic radiation in at least one of the infrared region and the visible region of the electromagnetic radiation spectrum; selecting the at least one chamber wall to comprise a transparent material at least substantially transparent to electromagnetic radiation over the range of wavelengths; positioning a sensor of at least one metrology device outside and proximate to the reaction chamber; orienting the sensor to receive an electromagnetic radiation signal passing from an interior of the reaction chamber to an exterior of the reaction chamber; selecting the sensor to comprise a sensor configured to detect the electromagnetic radiation signal at one or more wavelengths within the range of wavelengths; providing at least one volume of opaque material at a location preventing at least some thermal radiation to be emitted by the at least one thermal radiation emitter from being detected by the sensor of the at least one metrology device; and selecting the opaque material to comprise a material opaque to wavelengths of electromagnetic radiation within the range of wavelengths.

### Embodiment 20

The method of Embodiment 19, further comprising selecting at least one chamber wall of the one or more chamber walls to comprise the at least one volume of opaque material.

### Embodiment 21

The method of Embodiment 20, further comprising: positioning a body within the interior of the reaction chamber; and selecting the body to comprise another volume of opaque material.

### Embodiment 22

The method of Embodiment 19, further comprising: positioning a body within the interior of the reaction chamber; and selecting the body to comprise the at least one volume of opaque material.

### Embodiment 23

The method of Embodiment 22, further comprising selecting the body to comprise a generally planar plate-shaped structure.

### Embodiment 24

The method of any one of Embodiments 19 through 23, further comprising selecting the one or more chamber walls of the reaction chamber to include a top wall, a bottom wall, and at least one side wall extending between the top wall and the bottom wall.

### Embodiment 25

The method of Embodiment 24, further comprising positioning the at least one thermal radiation emitter adjacent the bottom wall.

### Embodiment 26

The method of Embodiment 24 or Embodiment 25, further comprising selecting the bottom wall to comprise the transparent material.

### Embodiment 27

The method of any one of Embodiments 24 through 26, further comprising selecting the bottom wall to comprise transparent quartz.

### Embodiment 28

The method of any one of Embodiments 24 through 27, further comprising selecting the top wall to comprise the at least one volume of opaque material.

### Embodiment 29

The method of any one of Embodiments 24 through 28, further comprising selecting the at least one side wall to comprise the at least one volume of opaque material.

### Embodiment 30

The method of any one of Embodiments 24 through 29, further comprising positioning the sensor of the at least one metrology device adjacent the top wall.

### Embodiment 31

The method of Embodiment 30, further comprising selecting the top wall to include at least a portion comprising the transparent material.

### Embodiment 32

The method of any one of Embodiments 24 through 31, further comprising: positioning the at least one thermal radiation emitter outside the reaction chamber adjacent the bottom wall; selecting the bottom wall to comprise the transparent material; and positioning the sensor of the at least one metrology device outside the reaction chamber adjacent the top wall.

### Embodiment 33

The method of Embodiment 32, further comprising selecting at least one of the top wall and the at least one side wall to comprise the at least one volume of opaque material.

### Embodiment 34

The method of Embodiment 32 or Embodiment 33, further comprising: positioning a body within the interior of the reaction chamber; and selecting the body to comprise the at least one volume of opaque material.

### Embodiment 35

A method of depositing material on a workpiece substrate using a deposition system, comprising: positioning at least one workpiece substrate within an interior of a reaction chamber; emitting thermal radiation into the interior of the reaction chamber from at least one thermal radiation emitter outside the reaction chamber through at least a portion of one or more chamber walls of the reaction chamber comprising a transparent material transparent to the thermal radiation; introducing at least one process gas into the reaction chamber; heating at least one of the workpiece substrate and the at least one process gas using the thermal radiation; depositing material on the at least one workpiece substrate from the at least one process gas; sensing an electromagnetic radiation signal representative of at least one characteristic of the at least one workpiece substrate using a sensor of at least one metrology device outside and proximate to the reaction chamber, the electromagnetic radiation signal passing from the interior of the reaction chamber to the sensor through one or more chamber walls of the reaction chamber transparent to the electromagnetic radiation signal; and shielding the sensor from at least some of the thermal radiation using at least one volume of opaque material.

### Embodiment 36

The method of Embodiment 35, wherein shielding the sensor from at least some of the thermal radiation using at least one volume of opaque material comprises shielding the sensor from at least some of the thermal radiation using at least one chamber wall of the one or more chamber walls, the at least one chamber wall comprising the at least one volume of opaque material.

### Embodiment 37

The method of Embodiment 35 or Embodiment 36, wherein shielding the sensor from at least some of the thermal radiation using at least one volume of opaque material comprises shielding the sensor from at least some of the thermal radiation using at least one body positioned in the interior of the reaction chamber, the at least one body comprising the at least one volume of opaque material.

The embodiments of the invention described above do not limit the scope of the invention, since these embodiments are merely examples of embodiments of the invention, which is defined by the scope of the appended claims and their legal equivalents. Any equivalent embodiments are intended to be within the scope of this invention. Indeed, various modifications of the invention, in addition to those shown and described herein, such as alternate useful combinations of the elements described, will become apparent to those skilled in the art from the description. Such modifications are also intended to fall within the scope of the appended claims.

What is claimed is:

1. A deposition system, comprising:
a reaction chamber including one or more chamber walls;
at least one thermal radiation emitter configured to emit thermal radiation within a range of wavelengths of electromagnetic radiation in at least one of the infrared region and the visible region of the electromagnetic radiation spectrum through at least one chamber wall of the one or more chamber walls and into an interior of the reaction chamber, the at least one chamber wall comprising a transparent material at least substantially transparent to electromagnetic radiation over the range of wavelengths;
at least one metrology device including a sensor located outside the reaction chamber and oriented and configured to receive an electromagnetic radiation signal at one or more wavelengths within the range of wavelengths passing from an interior of the reaction chamber to an exterior of the reaction chamber; and
at least one volume of opaque material, the opaque material being opaque to wavelengths of electromagnetic radiation within the range of wavelengths, the at least one volume of the opaque material located to prevent at least some thermal radiation to be emitted by the at least one thermal radiation emitter from being detected by the sensor of the at least one metrology device.

2. The deposition system of claim 1, wherein the at least one volume of opaque material comprises at least a portion of a chamber wall of the one or more chamber walls.

3. The deposition system of claim 1, further comprising a body positioned within the interior of the reaction chamber, the body comprising the at least one volume of opaque material.

4. The deposition system of claim 3, wherein the body positioned within the interior of the reaction chamber comprises a generally planar plate-shaped structure.

5. The deposition system of claim 1, wherein the one or more chamber walls of the reaction chamber include a top wall, a bottom wall, and at least one side wall extending between the top wall and the bottom wall.

6. The deposition system of claim 5, wherein the at least one thermal radiation emitter is disposed adjacent the bottom wall.

7. The deposition system of claim 6, wherein the bottom wall comprises the transparent material.

8. The deposition system of claim 7, wherein the bottom wall comprises transparent quartz.

9. The deposition system of claim 8, wherein at least a portion of the top wall comprises the at least one volume of opaque material, and wherein the opaque material comprises opaque quartz.

10. The deposition system of claim 8, wherein at least a portion of the at least one side wall comprises the at least one volume of opaque material, and wherein the opaque material comprises opaque quartz.

11. The deposition system of claim 5, wherein the sensor of the at least one metrology device is disposed adjacent the top wall.

12. The deposition system of claim 11, wherein at least a portion of the top wall comprises the at least one volume of opaque material, and wherein the opaque material comprises opaque quartz.

13. The deposition system of claim 11, wherein at least a portion of the at least one side wall comprises the at least one volume of opaque material, and wherein the opaque material comprises opaque quartz.

14. The deposition system of claim 5, wherein the at least one thermal radiation emitter is disposed outside the reaction chamber adjacent the bottom wall, at least a portion of the bottom wall comprises the transparent material, and the sensor of the at least one metrology device is disposed outside the reaction chamber adjacent the top wall.

15. The deposition system of claim 14, wherein at least one of the top wall and the at least one side wall comprises the at least one volume of opaque material.

16. The deposition system of claim 14, wherein the at least one volume of opaque material is disposed within the interior of the reaction chamber between the top wall and the bottom wall.

17. The deposition system of claim 1, wherein the at least one thermal radiation emitter comprises a plurality of lamps.

18. The deposition system of claim 1, wherein the transparent material comprises transparent quartz.

19. The deposition system of claim 1, wherein the opaque material comprises opaque quartz.

20. A method of forming a deposition system, comprising:
positioning at least one thermal radiation emitter outside and proximate to a reaction chamber including one or more chamber walls;
orienting the at least one thermal radiation emitter to emit thermal radiation through at least one chamber wall of the one or more chamber walls and into an interior of the reaction chamber;
selecting the at least one thermal radiation emitter to comprise an emitter configured to emit thermal radiation within a range of wavelengths of electromagnetic radiation in at least one of the infrared region and the visible region of the electromagnetic radiation spectrum;
selecting the at least one chamber wall of the one or more chamber walls to comprise a transparent material at least substantially transparent to electromagnetic radiation over the range of wavelengths;
positioning a sensor of at least one metrology device outside and proximate to the reaction chamber;
orienting the sensor to receive an electromagnetic radiation signal passing from an interior of the reaction chamber to an exterior of the reaction chamber;
selecting the sensor to comprise a sensor configured to detect the electromagnetic radiation signal at one or more wavelengths within the range of wavelengths;
providing at least one volume of opaque material at a location preventing at least some thermal radiation to be emitted by the at least one thermal radiation emitter from being detected by the sensor of the at least one metrology device; and
selecting the opaque material to comprise a material opaque to wavelengths of electromagnetic radiation within the range of wavelengths.

21. The method of claim 20, further comprising selecting at least one chamber wall of the one or more chamber walls to comprise the at least one volume of opaque material.

22. The method of claim 20, further comprising:
positioning a body within the interior of the reaction chamber; and
selecting the body to comprise the at least one volume of opaque material.

23. The method of claim 22, further comprising selecting the body to comprise a generally planar plate-shaped structure.

24. The method of claim 20, further comprising selecting the one or more chamber walls of the reaction chamber to include a top wall, a bottom wall, and at least one side wall extending between the top wall and the bottom wall.

25. The method of claim 24, further comprising positioning the at least one thermal radiation emitter adjacent the bottom wall.

26. The method of claim 25, further comprising selecting the bottom wall to comprise the transparent material.

27. The method of claim 26, further comprising selecting the bottom wall to comprise transparent quartz.

28. The method of claim 27, further comprising selecting the top wall to comprise the at least one volume of opaque material, and wherein the opaque material comprises opaque quartz.

29. The method of claim 27, further comprising selecting the at least one side wall to comprise the at least one volume of opaque material, and wherein the opaque material comprises opaque quartz.

30. The method of claim 24, further comprising positioning the sensor of the at least one metrology device adjacent the top wall.

31. The method of claim 30, further comprising selecting the top wall to comprise the at least one volume of opaque material, and wherein the opaque material comprises opaque quartz.

32. The method of claim 30, further comprising selecting the at least one side wall to comprise the at least one volume of opaque material, and wherein the opaque material comprises opaque quartz.

33. The method of claim 24, further comprising:
positioning the at least one thermal radiation emitter outside the reaction chamber adjacent the bottom wall;
selecting the bottom wall to comprise the transparent material; and
positioning the sensor of the at least one metrology device outside the reaction chamber adjacent the top wall.

34. The method of claim 33, further comprising selecting at least one of the top wall and the at least one side wall to comprise the at least one volume of opaque material.

35. The method of claim 33, further comprising:
positioning a body within the interior of the reaction chamber; and
selecting the body to comprise the at least one volume of opaque material.

36. A method of depositing material on a workpiece substrate using a deposition system, comprising:
positioning at least one workpiece substrate within an interior of a reaction chamber;
emitting thermal radiation into the interior of the reaction chamber from at least one thermal radiation emitter outside the reaction chamber through at least a portion of one or more chamber walls of the reaction chamber comprising a transparent material transparent to the thermal radiation;
introducing at least one process gas into the reaction chamber;
heating at least one of the at least one workpiece substrate and the at least one process gas using the thermal radiation;
depositing material on the at least one workpiece substrate from the at least one process gas;
sensing an electromagnetic radiation signal representative of at least one characteristic of the at least one workpiece substrate using a sensor of at least one metrology device outside and proximate to the reaction chamber, the electromagnetic radiation signal passing from the interior of the reaction chamber to the sensor through one or more chamber walls of the reaction chamber transparent to the electromagnetic radiation signal; and
shielding the sensor from at least some of the thermal radiation using at least one volume of opaque material.

37. The method of claim 36, wherein shielding the sensor from at least some of the thermal radiation using at least one volume of opaque material comprises shielding the sensor from at least some of the thermal radiation using at least one chamber wall of the one or more chamber walls, the at least one chamber wall comprising the at least one volume of opaque material.

38. The method of claim 36, wherein shielding the sensor from at least some of the thermal radiation using at least one volume of opaque material comprises shielding the sensor from at least some of the thermal radiation using at least one body positioned in the interior of the reaction chamber, the at least one body comprising the at least one volume of opaque material.
